(19) United States
(12) Patent Application Publication
(10) Pub. No.: US 2024/0387422 A1
(43) Pub. Date: Nov. 21, 2024

(54) SEMICONDUCTOR STRUCTURE AND METHOD FOR FORMING THE SAME

(71) Applicant: MEDIATEK INC., Hsinchu City (TW)

(72) Inventors: Cheng-Lin HUANG, Hsinchu City (TW); Ting-Li YANG, Hsinchu City (TW)

(21) Appl. No.: 18/637,760

(22) Filed: Apr. 17, 2024

Related U.S. Application Data
(60) Provisional application No. 63/503,180, filed on May 19, 2023.

(51) Int. Cl. H01L 23/00

(52) U.S. Cl. CPC H01L 24/05; H01L 24/03; H01L 24/06; H01L 24/13; H01L 2224/02206; H01L 2224/0221; H01L 2224/02215; H01L 2224/03013; H01L 2224/0401; H01L 2224/05147; H01L 2224/0603; H01L 2224/13026; H01L 2224/13147; H01L 2924/05042; H01L 2924/05442; H01L 2924/05994; H01L 2924/06; H01L 2924/07025; H01L 2924/30101; H01L 2924/30105

(57) ABSTRACT

A semiconductor structure is provided. The semiconductor structure includes an interconnection structure, a passivation layer and a dielectric capping layer. The interconnect structure has a conductive pad located at a top of the interconnection structure. The passivation layer is disposed on the interconnection structure. The passivation layer has a first opening to expose a portion of the conductive pad. The dielectric capping layer is conformally formed on the passivation layer and extends into the first opening. The dielectric capping layer has a second opening to expose the portion of the conductive pad.

### CROSS REFERENCE TO RELATED APPLICATIONS

This application claims the benefit of U.S. Provisional Application No. 63/503,180, filed May 19, 2023, the entirety of which is incorporated by reference herein.

### BACKGROUND OF THE INVENTION

### Field of the Invention

The present invention relates to a semiconductor structure and a method for forming the semiconductor structure, and, in particular, to a semiconductor structure that has an improved resistance-capacitance (RC) time constant and a method for forming the semiconductor structure.

### Description of the Related Art

In recent years, advanced integrated circuit (IC) devices have become increasingly multifunctional and have been scaled down in terms of size. Although the scaling-down process generally increases production efficiency and lowers associated costs, it has also increased the complexity of processing and manufacturing IC devices. For example, the need has arisen in the semiconductor manufacturing process to move to copper (Cu)-based interconnects integrated with low-k dielectrics in order to dramatically reduce chip resistivity (R) and capacitance (C). Copper has lower resistivity than Al-based alloys. Therefore, the semiconductor devices fabricated with Cu-based interconnects will show reduced resistance-capacitance (RC) delays. However, the copper oxidation rate is high when there is no self-passivation layer formed to prevent the underlying copper from further oxidation. Therefore, the formation of a layer of oxide on a copper pad could be a serious concern in the following bumping processes.

Thus, a novel semiconductor structure having an improved resistance-capacitance (RC) time constant is desirable.

### BRIEF SUMMARY OF THE INVENTION

An embodiment of the present invention provides a semiconductor structure. The semiconductor structure includes an interconnection structure, a passivation layer and a dielectric capping layer. The interconnect structure includes a conductive pad located at a top of the interconnection structure. The passivation layer is disposed on the interconnection structure. The passivation layer has a first opening to expose a portion of the conductive pad. The dielectric capping layer is conformally formed on the passivation layer and extends into the first opening. The dielectric capping layer has a second opening to expose the portion of the conductive pad.

In addition, an embodiment of the present invention provides a method for forming a semiconductor structure. The method includes forming an interconnect structure on a substrate. The interconnect structure includes a conductive pad and a first passivation layer. The conductive pad is located at a top of the interconnection structure. The first passivation layer is disposed underlying the conductive pad. The method further includes forming a first opening passing through the second passivation layer to expose a portion of the conductive pad. The method further includes conformally forming a dielectric capping layer on the second passivation layer. A top surface of the conductive pad is fully covered by the first passivation layer and the dielectric capping layer before forming a conductive bump structure on the conductive pad.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor structure in accordance with some embodiments of the disclosure;

FIG. 2 is a schematic cross-sectional view of a semiconductor structure in accordance with some embodiments of the disclosure;

FIG. 3 is a schematic cross-sectional view of a semiconductor structure in accordance with some embodiments of the disclosure;

FIGS. 4, 5, 6, 7, 8, and 9 are schematic cross-sectional views of intermediate stages of forming the semiconductor structure of FIG. 1 in accordance with some embodiments of the disclosure;

FIG. 10 is a schematic cross-sectional view of an intermediate stage of forming the semiconductor structure of FIG. 2 in accordance with some embodiments of the disclosure; and

FIG. 11 is a schematic cross-sectional view of an intermediate stage of forming the semiconductor structure of FIG. 3 in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

Copper (Cu) pads are widely adopted in the advanced semiconductor devices. Compared with the conventional aluminum (Al) pads, the Cu pads have lower parasitic resistance-capacitance values (RC) for performance improvement. However, when the semiconductor wafers or dies is in the long queue storage before forming the bump structures, the oxidation of the Cu pads may impact the parasitic resistance-capacitance values (RC) of the bump structures in the following bumping process, thereby affecting the reliability and manufacturing quality of the semiconductor devices. Thus, a novel semiconductor structure having low parasitic resistance-capacitance values (RC) is desirable.

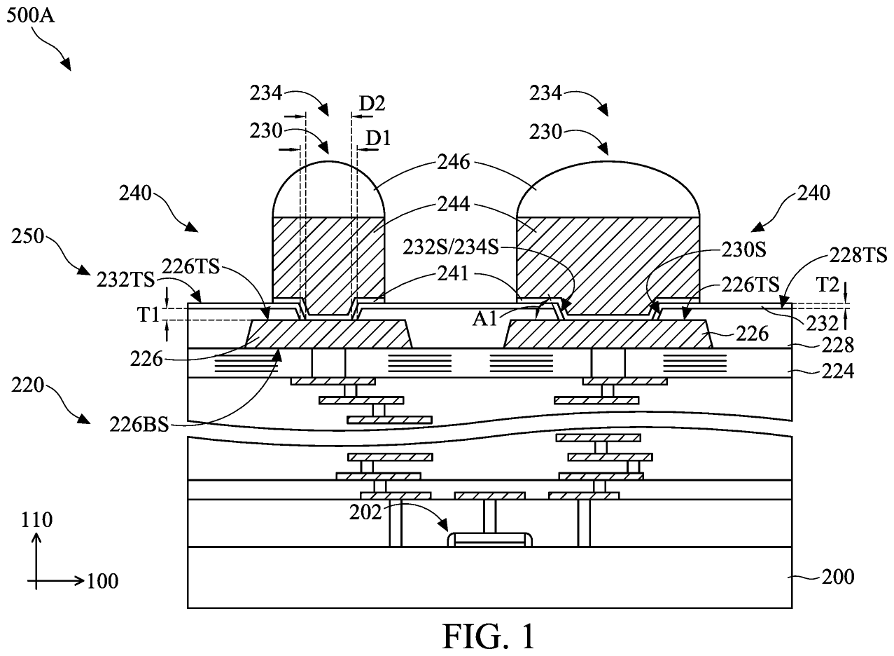

FIG. 1 is a schematic cross-sectional view of a semiconductor structure 500A in accordance with some embodiments of the disclosure. In some embodiments, the semiconductor structure 500A includes a semiconductor device using conductive bump structures connecting a base (not shown) such as a printed circuit board (PCB). The semiconductor structure 500A may include a semiconductor device 250 and a conductive bump structure 240 electrically coupled to the semiconductor device 250. In some embodiments, the semiconductor device includes a semiconductor die, a passive component, a package or a wafer level package. In some embodiments, the semiconductor device 250 may include a substrate 200, an interconnect structure 220, a first passivation layer 224 and a conductive pad 226. The semiconductor structure 500A may further include a second passivation layer 228 and a dielectric capping layer 232 on the semiconductor device 250.

In some embodiments, the substrate 200 may include but is not limited to a semiconductor substrate. The substrate 200 may be provided for a circuit element 202 fabricated on the active surface of the substrate 200. In some embodiments, the circuit element 202 may include active devices, passive devices or other applicable devices. The interconnect structure 220 is formed on the substrate 200, covering the circuit element 202. In some embodiments, the interconnect structure 220 provides electrical transmitting paths for the circuit element 202. In some embodiments, the interconnect structure 220 includes a redistribution layer (RDL) structure having a plurality of metal layers, a plurality of dielectric layers alternatively laminated with the metal layers and a plurality of vias formed through the dielectric layers on the substrate 200. For example, the dielectric layers of the interconnect structure 220 may be extra-low-k (ELK) dielectric layers. For example, the metal layers of the interconnect structure 220 may comprise but is not limited to copper or alloys thereof.

The first passivation layer 224 is disposed over the substrate 200. The first passivation layer 224 belongs to the uppermost dielectric layer of the interconnect structure 220 and provides protection to the underlying circuit element 202. In some embodiments, the first passivation layer 224 may include an organic or inorganic dielectric layer, such as silicon oxide, silicon nitride, silicon oxynitride, polybenzoxazole (PBO), benzocyclobutene (BCB), the like, or a combination thereof.

The conductive pad 226 is located at the top of the interconnect structure 220. The conductive pad 226 is disposed on the first passivation layer 224. In other words, the first passivation layer 224 is disposed underlying a bottom surface 226BS of the conductive pad 226. In addition, the conductive pad 226 belongs to the uppermost metal layer of the interconnect structure 220. In addition, a top surface 226TS of the conductive pad 226 may be a flat surface. In some embodiments, the conductive pad 226 is used to transmit input/output (I/O), ground or power signals of the semiconductor device 250. In some embodiments, the conductive pad 226 may include copper (Cu) or alloys thereof.

The second passivation layer 228 is disposed on the top of the interconnect structure 220. The second passivation layer 228 may cover the first passivation layer 224 and a portion of the conductive pad 226. The second passivation layer 228 may provide protection to the underlying conductive pad 226. In addition, a top surface 228TS of the second passivation layer 228 may be a flat surface. In some embodiments, the second passivation layer 228 has an opening 230. The opening 230 is located directly on the conductive pad 226 to define the formation position of the subsequent conductive bump structure 240. In addition, the opening 230 is formed passing through the second passivation layer 228 to expose a portion of the conductive pad 226. In some embodiments, a thickness T1 of the second passivation layer 228 between the top surface 228TS and the top surface 226TS of the conductive pad 226 is between about 5 μm and 25 μm. In some embodiments, the first passivation layer 224 and the dielectric capping layer 232 are formed of the same material. In some embodiments, the second passivation layer 228 may be a multilayer structure including silicon oxide, silicon nitride, silicon oxynitride, polybenzoxazole (PBO), benzocyclobutene (BCB), the like, or a combination thereof.

The dielectric capping layer 232 is conformally forming on the second passivation layer 228. The dielectric capping layer 232 is used to protect the underlying conductive pad 226 before the bumping process. As shown in FIG. 1, the dielectric capping layer 232 may extend from the top surface 228TS of the second passivation layer 228 into the opening 230. In some embodiments, the dielectric capping layer 232 lines sidewalls 230S of the opening 230. In addition, the dielectric capping layer 232 may be in contact with the second passivation layer 228 and the portion of the conductive pad 226 exposed from the opening 230. Furthermore, a top surface 232TS of the dielectric capping layer 232 may be a flat surface because the top surface 226TS of the underlying conductive pad 226 and the top surface 228TS of the underlying second passivation layer 228 are flat surfaces.

As shown in FIG. 1, the dielectric capping layer 232 has an opening 234 to expose the portion of the conductive pad 226. In addition, the opening 234 is located within and aligned with the opening 230. In a direction 100 that is substantially parallel to the top surface 228TS of the second passivation layer 228, the opening 230 has a dimension D1, and the opening 234 has a dimension D2. In some embodiments, the dimension D2 is less than the dimension D1.

In some embodiments, a thickness T2 of the dielectric capping layer 232 is between about 25 Å and 50 μm. If the thickness T2 is less than 25 Å, the dielectric capping layer 232 may be not thick enough to protect the underlying conductive pad 226 during forming the opening 234. If the thickness T2 is greater than 50 μm, the dielectric capping layer 232 may have residue on the top surface 226TS of the conductive pad 226 after forming the opening 234. In some embodiments, the thickness T2 of the dielectric capping layer 232 may be thinner than the thickness T1 of the second passivation layer 228.

In some embodiments, an angle A1 between a side surface 232S of the dielectric capping layer 232 in the opening 230 and away from the second passivation layer 228 and the top surface 226TS of the conductive pad 226 is less than or equal to 95 degrees. If the angle A1 is greater than 95 degrees, a seed layer (e.g., a seed layer of an under bump metallurgy (UBM) layer 241 and would be described later) of the subsequent conductive bump structure 240 formed on the dielectric capping layer 232 by the deposition process including physical vapor deposition (PVD) may be formed as a discontinuous layer. The discontinuous seed layer may impact the reliability of the resulting semiconductor structure 500A.

In some embodiments, the dielectric capping layer 232 includes a dielectric layer, such as silicon oxide, silicon nitride, silicon oxynitride, the like, or a combination thereof. In some embodiments, the dielectric capping layer 232 includes a polymer layer, for example, polybenzoxazole (PBO), benzocyclobutene (BCB), epoxy, the like, or a combination thereof. In some embodiments, the second passivation layer 228 and the dielectric capping layer 232 are formed of different materials. For example, the second passivation layer 228 is silicon oxide, and the dielectric capping layer 232 is polybenzoxazole (PBO). In some embodiments, the dielectric capping layer 232 is formed by a deposition process such as chemical vapor deposition (CVD), spin-on coating or another applicable deposition process, and a subsequent patterning process such as dry etching.

The conductive bump structure 240 is disposed on the second passivation layer 228 and the dielectric capping layer 232. In addition, the conductive bump structure 240 is formed passing through the openings 230, 234 and connected to the conductive pad 226. In some embodiments, the dielectric capping layer 232 is interposed between the second passivation layer 228 and the conductive bump structure 240. In addition, a portion of the dielectric capping layer 232 that is located on the top surface 228TS of the second passivation layer 228 is exposed from the conductive bump structure 240. In this embodiment, the conductive bump structure 240 is in contact with the dielectric capping layer 232 and the conductive pad 226. In addition, the dielectric capping layer 232 is directly connected between the second passivation layer 228 and the conductive bump structure 240. In some embodiments, the conductive bump structure 240 includes a microbump, a copper pillar bump, a controlled collapse chip connection (C4) bump, the like, or a combination thereof. For example, the conductive bump structure 240 may include the under bump metallurgy (UBM) layer 241, a conductive pillar 244 on the UBM layer 241, and a solder cap 246 on the conductive pillar 244.

As shown in FIG. 1, the under bump metallurgy (UBM) layer 241 of the conductive bump structure 240 is formed passing through the opening 234 of dielectric capping layer 232 and the opening 230 of the second passivation layer 228 and overlying the conductive pad 226. The UBM layer 241 may line the sidewalls 234S of the opening 234 of the dielectric capping layer 232 and the top surface 226TS of the conductive pad 226 in the opening 234. The sidewalls 234S of the opening 234 of the dielectric capping layer 232 is also located at the side surface 232S of the dielectric capping layer 232 in the opening 230 and away from the second passivation layer 228. The UBM layer 241 may also extend onto the top surface 232TS of the dielectric capping layer 232. In some embodiments, the UBM layer 241 includes a seed layer (not shown), such as a pure copper (Cu) layer, a pure titanium (Ti) layer, a Ti/Cu layer, a TiW/Cu layer, any other metal layer, and combinations thereof. In some other embodiments, the seed layer of the UBM layer 241 includes a titanium nitride (TiN) layer, a tantalum (Ta) layer, or a tantalum nitride (TaN) layer, a silver (Ag) layer, a gold (Au) layer, an aluminum (Al) layer, and combinations thereof. In some other embodiments, the UBM layer 241 include a nickel (Ni) layer is formed on the seed layer. In some embodiments, the UBM layer 241 is formed by a deposition method includes a physical vapor deposition (PVD), such as a sputtering or plating method.

The conductive pillar 244 of the conductive bump structure 240 is formed on the UBM layer 241, as shown in FIG. 1 in accordance with some embodiments of the disclosure. In some embodiments, the conductive pillar 244 and the seed layer of the UBM layer 241 may comprise the same material, such as copper (Cu). In some embodiments, the conductive pillar 244 is formed by a photolithography process and a subsequent electroplating process.

The solder cap 246 is formed on conductive pillar 244 by a solder plating process or a screen printing process, a photoresist stripping process, and a solder reflow process.

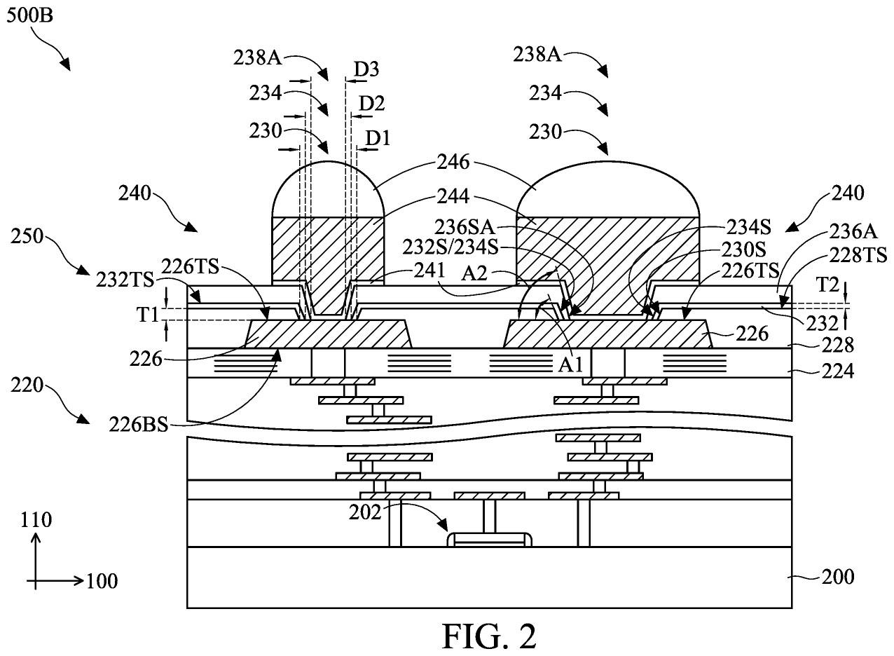

FIG. 2 is a schematic cross-sectional view of a semiconductor structure 500B in accordance with some embodiments of the disclosure. Elements of the embodiments hereinafter, that are the same or similar as those previously described with reference to FIG. 1, are not repeated for brevity. As shown in FIG. 2, the difference between the semiconductor structure 500A and the semiconductor structure 500B at least includes that the semiconductor structure 500B further includes a photosensitive stress buffer layer 236A. In some embodiments, the photosensitive stress buffer layer 236A is used for providing reliable insulation when the semiconductor device 250 is subjected to various types of environmental stress.

The photosensitive stress buffer layer 236A may be conformally formed on the dielectric capping layer 232. In this embodiment, the photosensitive stress buffer layer 236A may extend from the top surface 232TS of the dielectric capping layer 232 into the openings 230 and 234. More specifically, the photosensitive stress buffer layer 236A lines the dielectric capping layer 232 in the opening 230 and sidewalls 234S of the opening 234 of the dielectric capping layer 232. In addition, the photosensitive stress buffer layer 236A is in contact with a portion of the conductive pad 226 exposed from the opening 234. As shown in FIG. 2, the conductive bump structure 240 may be separated from the second passivation layer 228 by the dielectric capping layer 232 and the photosensitive stress buffer layer 236A.

As shown in FIG. 2, the photosensitive stress buffer layer 236A has an opening 238A to expose the portion of the conductive pad 226. In some embodiments, the opening 238A of photosensitive stress buffer layer 236A is located within and aligned with the opening 234 of the dielectric capping layer 232 and the opening 230 of the second passivation layer 228. In the direction 100 substantially parallel to the top surface 228TS of the second passivation layer 228, the opening 238A has a dimension D3. In some embodiments, the dimension D3 is less than the dimension D2.

In some embodiments, an angle A2 between a side surface 236SA of the photosensitive stress buffer layer 236A away from the dielectric capping layer 232 located in the opening 234 and on the top surface 226TS of the conductive pad 226 is less than or equal to 95 degrees. If the angle A2 is greater than 95 degrees, a seed layer (e.g., a seed layer of the under bump metallurgy (UBM) layer 241) of the subsequent conductive bump structure 240 formed on the photosensitive stress buffer layer 236A by the deposition process including physical vapor deposition (PVD) may be formed as a discontinuous layer. The discontinuous seed layer may impact the reliability of the resulting semiconductor structure 500B.

In some embodiments, the photosensitive stress buffer layer 236A may include polyimide or another applicable photosensitive material. In some embodiments, the photosensitive stress buffer layer 236A is formed by a coating process, a photolithography process and a subsequent a curing process. In this embodiment, the photosensitive stress buffer layer 236A of the semiconductor structure 500B may have a PI (polyimide) pull-in structure because the photosensitive stress buffer layer 236A pulls in the opening 230 of the second passivation layer 228.

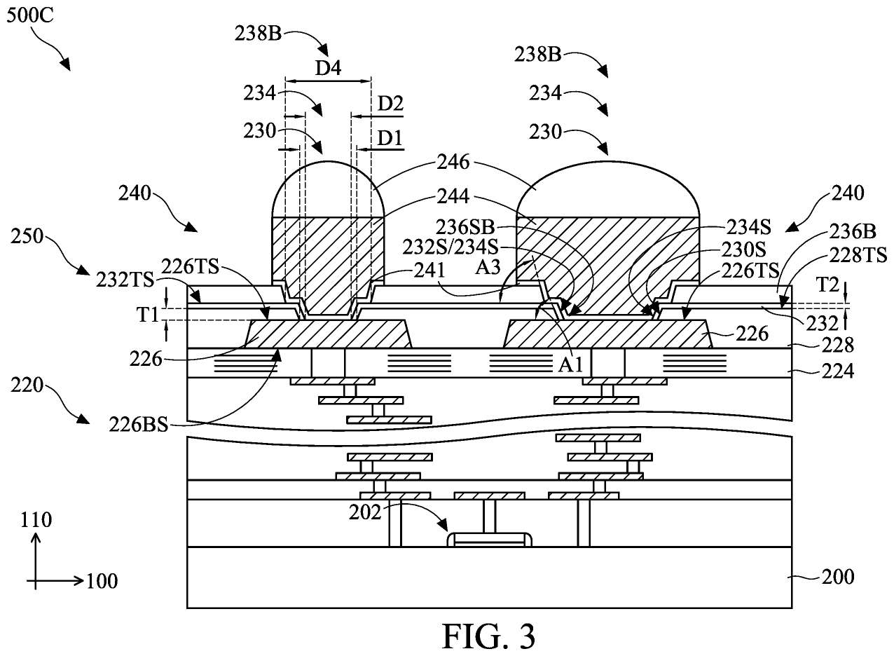

FIG. 3 is a schematic cross-sectional view of a semiconductor structure 500C in accordance with some embodiments of the disclosure. Elements of the embodiments hereinafter, that are the same or similar as those previously described with reference to FIGS. 1 and 2, are not repeated for brevity. As shown in FIG. 3, the difference between the semiconductor structure 500B and the semiconductor structure 500C at least includes that the semiconductor structure 500C further includes a photosensitive stress buffer layer 236B.

In this embodiment, the photosensitive stress buffer layer 236B is located above the opening 230 of the second passivation layer 228 and the opening 234 of the dielectric capping layer 232. The photosensitive stress buffer layer 236B may not extend into the openings 230 and 234. More specifically, the photosensitive stress buffer layer 236B may be spaced apart from the sidewalls 234S of the opening 234 of the dielectric capping layer 232. In addition, the photosensitive stress buffer layer 236B is spaced apart from the portion of the conductive pad 226 exposed from the opening 234. As shown in FIG. 3, the conductive bump structure 240 may be in contact with the dielectric capping layer 232 and the photosensitive stress buffer layer 236B.

As shown in FIG. 3, the photosensitive stress buffer layer 236B has an opening 238B to expose a portion of the dielectric capping layer 232 on the top surface 228TS and in the opening 230 of the second passivation 228. In addition, the opening 238B may expose the portion of the conductive pad 226 in the opening 234 of the dielectric capping layer 232. In some embodiments, the opening 234 of the dielectric capping layer 232 is located within and aligned with the opening 238B of photosensitive stress buffer layer 236B in the direction 110 that is substantially perpendicular to the top surface 228TS of the second passivation layer 228. In the direction 100 substantially parallel to the top surface 228TS of the second passivation layer 228, the opening 238B has a dimension D4. In some embodiments, the dimension D4 is greater than the dimensions D1, D2 and D3 (FIG. 2).

In some embodiments, an angle A3 between a side surface 236SB of the photosensitive stress buffer layer 236B surrounding the opening 238B and a bottom surface (also located at the top surface 232TS of the dielectric capping layer 232) of the photosensitive stress buffer layer 236B is less than or equal to 95 degrees. If the angle A3 is greater than 95 degrees, a seed layer (e.g., a seed layer of the under bump metallurgy (UBM) layer 241) of the subsequent conductive bump structure 240 formed on the photosensitive stress buffer layer 236B by the deposition process including physical vapor deposition (PVD) may be formed as a discontinuous layer. The discontinuous seed layer may impact the reliability of the resulting semiconductor structure 500C.

In some embodiments, the processes and the materials for forming the photosensitive stress buffer layer 236A (FIG. 2) may be similar to, or the same as, those for forming the photosensitive stress buffer layer 236B. In this embodiment, the photosensitive stress buffer layer 236B of the semiconductor structure 500C may have a PI (polyimide) pull-out structure because the photosensitive stress buffer layer 236B pulls out the opening 230 of the second passivation layer 228.

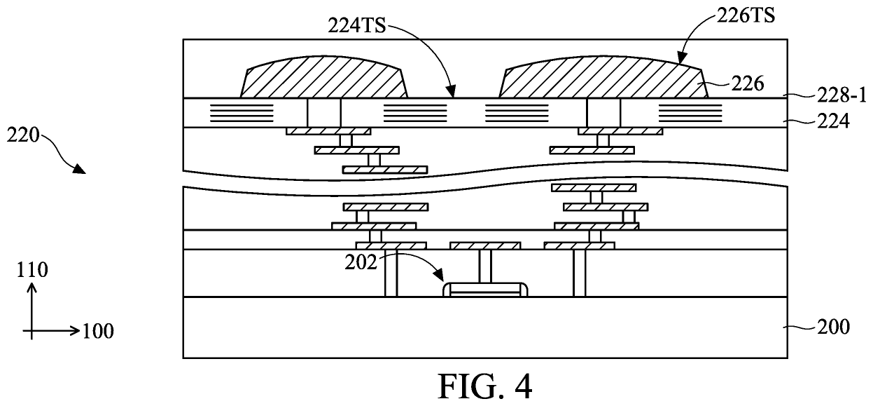

The method for forming the semiconductor structure 500A will be described below. FIGS. 4, 5, 6, 7, 8, and 9 are schematic cross-sectional views of intermediate stages of forming the semiconductor structure 500A of FIG. 1 in accordance with some embodiments of the disclosure. Elements of the embodiments hereinafter, that are the same or similar as those previously described with reference to FIGS. 1 to 3, are not repeated for brevity.

Please refer to FIG. 4, the substrate 200 is provided. Next, the circuit element 202 is formed on the substrate 200. Next, the interconnect structure 220 is formed on the substrate 200 and the circuit element 202. The interconnect structure 220 may include the conductive pad 226 located at the top of the interconnect structure 220 and electrically connected to the circuit element 202. Therefore, the semiconductor device 250 is formed. As shown in FIG. 4, the top surface 226TS of the conductive pad 226 is a convex surface.

Next, a lower portion 228-1 of the second passivation layer 228 (FIG. 1) is entirely formed on the interconnect structure 220 by a deposition process. The lower portion 228-1 of the second passivation layer 228 (FIG. 1) may fully cover the top surface 226TS of the conductive pad 226 and a top surface 224TS of first passivation layer 224 exposed from the conductive pad 226.

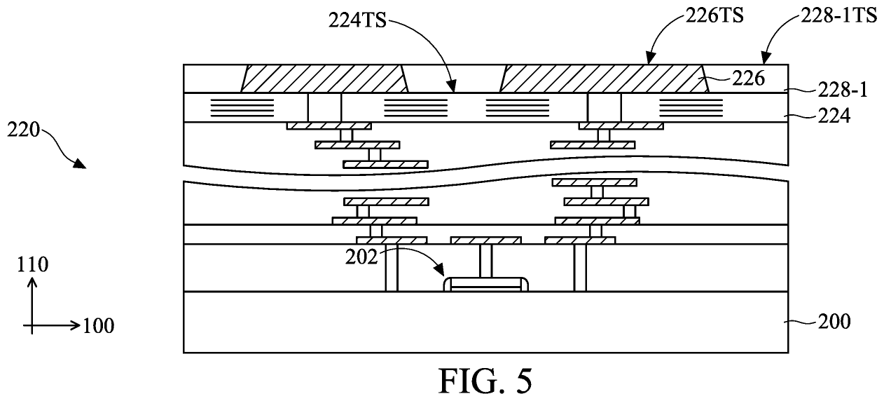

Please refer to FIG. 5, next, a planarization process is performed to remove a portion of the lower portion 228-1 of the second passivation layer 228 (FIG. 1) and a portion of the conductive pad 226 in order to planarize the tops of the lower portion 228-1 of the second passivation layer 228 (FIG. 1) and the conductive pad 226. As shown in FIG. 5, the top surface 226TS of the conductive pad 226 is a flat surface level with the top surface 228-1TS of the lower portion 228-1 of the second passivation layer 228 after the planarization process. More specifically, the top surface 226TS of the conductive pad 226 and the top surface 228-1TS of the lower portion 228-1 of the second passivation layer 228 are both flat surfaces that are level with each other after the planarization process. Therefore, the top surface (including the top surface 226TS of the conductive pad 226 and the top surface 228-1TS of the lower portion 228-1 of the second passivation layer 228) of the intermediate semiconductor structure shown in FIG. 5 is a flat surface. In some embodiments, the planarization process includes chemical mechanical polishing (CMP).

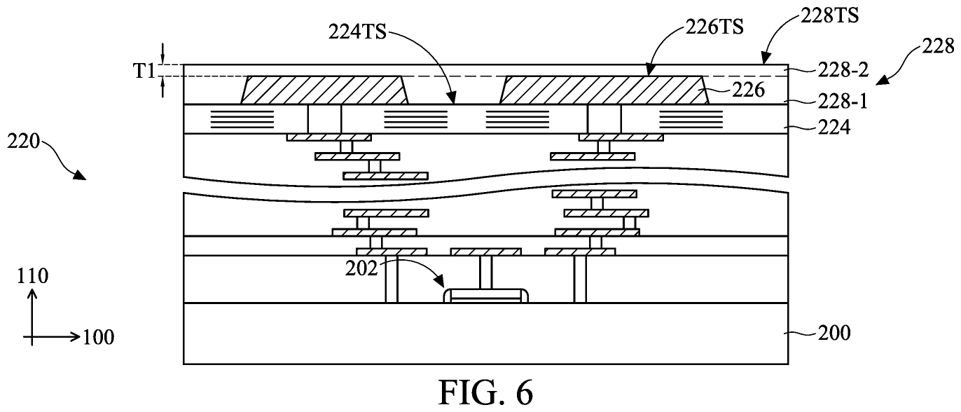

Please refer to FIG. 6, next, another deposition process is performed to form an upper portion 228-2 of the second passivation layer 228 covering the lower portion 228-1 of the second passivation layer 228 and the top surface 226TS of the conductive pad 226. Therefore, the second passivation layer 228 including the lower portion 228-1 and the upper portion 228-2 located on the lower portion 228-1 is formed on the interconnect structure 220. In addition, the top surface of the upper portion 228-2 of the second passivation layer 228 may serve as the top surface 228TS of the second passivation layer 228. In some embodiments, the thickness of the upper portion 228-2 of the second passivation layer 228 may serve as the thickness T1 of the second passivation layer 228 above the top surface 226TS of the conductive pad 226 and range between about 5 μm and 25 μm. Since the top surface of the intermediate semiconductor structure shown in FIG. 5 is a flat surface, the upper portion 228-2 of the second passivation layer 228 is formed to include a flat top surface after the deposition process. In some embodiments, the lower portion 228-1 and the upper portion 228-2 of the second passivation layer 228 may have the same or similar materials and fabrication processes. Therefore, the lower portion 228-1 and the upper portion 228-2 of the second passivation layer 228 may be formed as an integrated passivation layer without an interface therebetween.

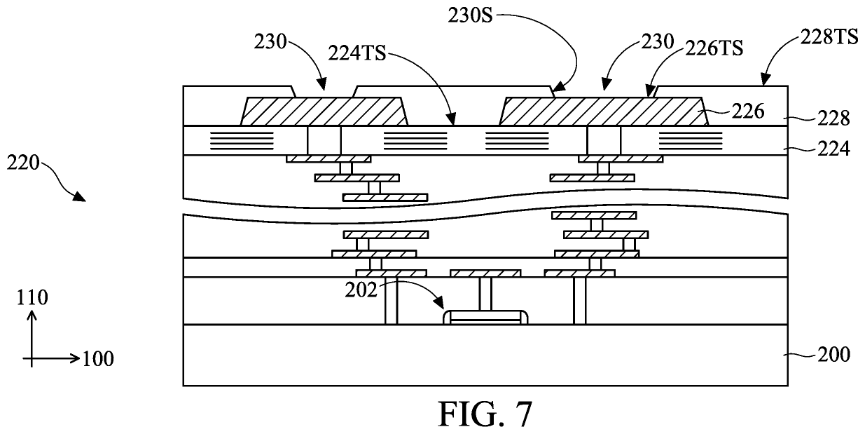

Please refer to FIG. 7, next, a patterning process is performed to from an opening 230 passing through the second passivation layer 228 above the conductive pad 226 (i.e., the upper portion 228-2 of the second passivation layer 228 shown in FIG. 6). The opening 230 is formed to expose a portion of the top surface 226TS of the conductive pad 226. In some embodiments, the patterning process includes a photolithography process and a subsequent anisotropic etching process such as dry etching.

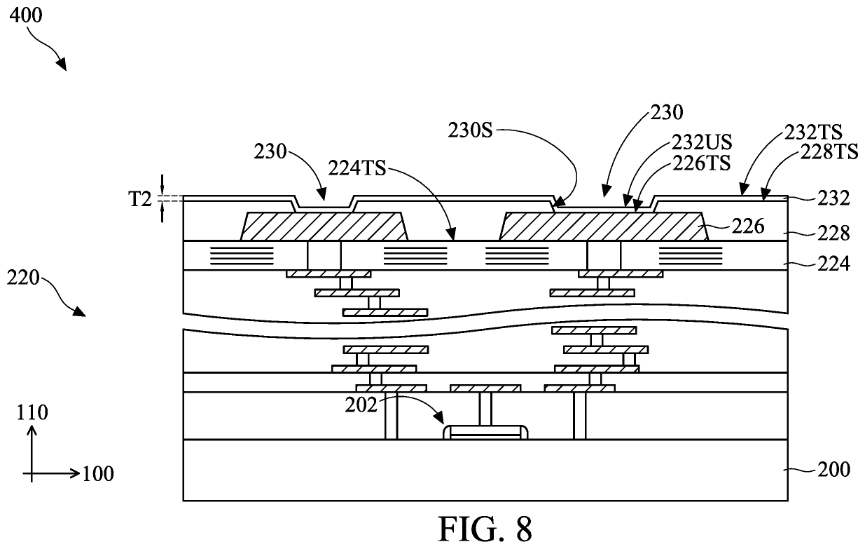

Please refer to FIG. 8, next, another deposition process is performed to conformally form the dielectric capping layer 232 on the second passivation layer 228. The dielectric capping layer 232 lines the top surface 228TS of the second passivation layer 228, the sidewalls 230S of the opening 230 and fully covers the top surface 226TS of the conductive pad 226 exposed from the opening 230. Accordingly, an intermediate semiconductor structure 400 of the semiconductor structure 500A in accordance with some embodiments of the disclosure is formed. As shown in FIG. 8, an upper surface 232US of the dielectric capping layer 232 in the opening 230 may be lower than the top surface 233TS of the dielectric capping layer 232 above the second passivation layer 228. In some embodiments, the thickness T2 of the dielectric capping layer 232 is between about 25 Å and 50 μm.

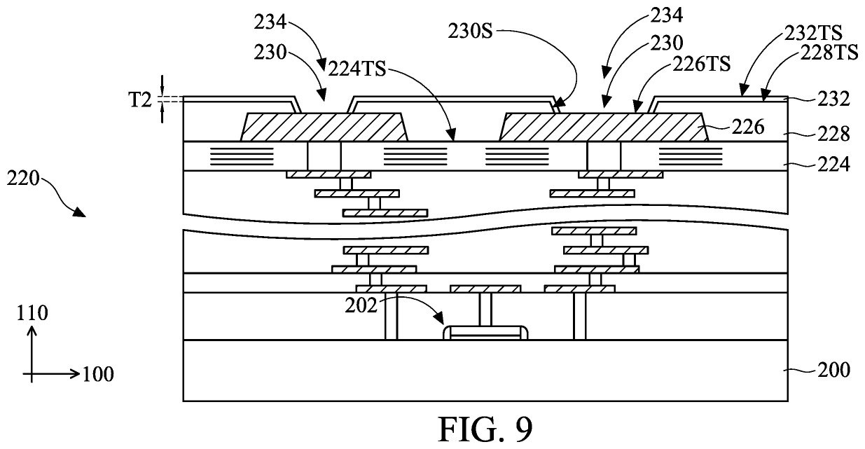

Please refer to FIG. 9, next, other patterning process is performed on the intermediate semiconductor structure 400 (FIG. 8) to from the opening 234 passing through the dielectric capping layer 232 to expose the portion of the conductive pad 226 within the opening 234. As shown in FIG. 9, the opening 234 is located within and aligned with the opening 230. In some embodiments, the patterning process includes a photolithography process and a subsequent anisotropic etching process such as dry etching. In some embodiments, the dry etching includes reactive plasma etching.

Since the intermediate semiconductor structure 400 shown in FIG. 8 in which the top surface 226TS of the conductive pad 226 is fully covered by the second passivation layer 228 and the dielectric capping layer 232 before forming the opening 234. In some embodiments, the dielectric capping layer 232 may serve as a protection layer for the underlying the conductive pad 226 exposed form the opening 230 of the second passivation layer 228 (FIG. 7). When the intermediate semiconductor structure 400 shown in FIG. 8 is in the long queue storage before performing the subsequent bumping process, the dielectric capping layer 232 may prevent the top surface 226TS of the conductive pad 226 from oxidation. When the intermediate semiconductor structure 400 shown in FIG. 8 will be subjected the bumping process, the opening 234 is formed passing through the dielectric capping layer 232 to expose the portion of the conductive pad 226 in the opening 234 for the subsequent conductive bump structure 240 formed thereon, as shown in FIG. 9.

Please refer to FIG. 1, next, a bumping process is performed to form the conductive bump structure 240 on the second passivation layer 228 and the dielectric capping layer 232. In addition, the conductive bump structure 240 is formed passing through the opening 230 and the opening 234 and connected to the conductive pad 226. In some embodiments, the bumping process includes blanket forming the under bump metallurgy (UBM) layer 241 on the second passivation layer 228 and the dielectric capping layer 232 by a deposition method.

As shown in FIG. 1, next, the bumping process further includes entirely forming a photoresist layer (not shown) on the UBM layer 241. In some embodiments, the photoresist layer includes a dry film photoresist or a liquid photoresist. Next, the photoresist layer is patterned by a photolithography process comprising an exposure step and a development step to form an opening (not shown) over the conductive pad 226. In some embodiments, the opening defines define a diameter and shape of the subsequent conductive pillar 244.

As shown in FIG. 1, next, the bumping process further includes forming the conductive pillar 244 on a portion of the UBM layer 241 without covered by the photoresist layer pattern. The conductive pillar 244 is formed filling the opening of the photoresist layer and covering a portion of the UBM layer 241 by electroplating or electrochemical deposition (ECD). Therefore, the conductive pillar 244 is formed through the photoresist layer and electrically connected to the conductive pad 226 through the UBM layer 241. In some embodiments, the conductive pillar 244 and the seed layer (not shown) of the UBM layer 241 are formed of the same material, such as copper (Cu).

As shown in FIG. 1, next, the bumping process further includes forming the solder cap 246 on the conductive pillar 244 by a solder plating process, a photoresist stripping process, and a solder reflow process. After the solder cap 246 is formed, the conductive bump structure 240 is formed. Accordingly, the semiconductor structure 500A in accordance with some embodiments of the disclosure is formed.

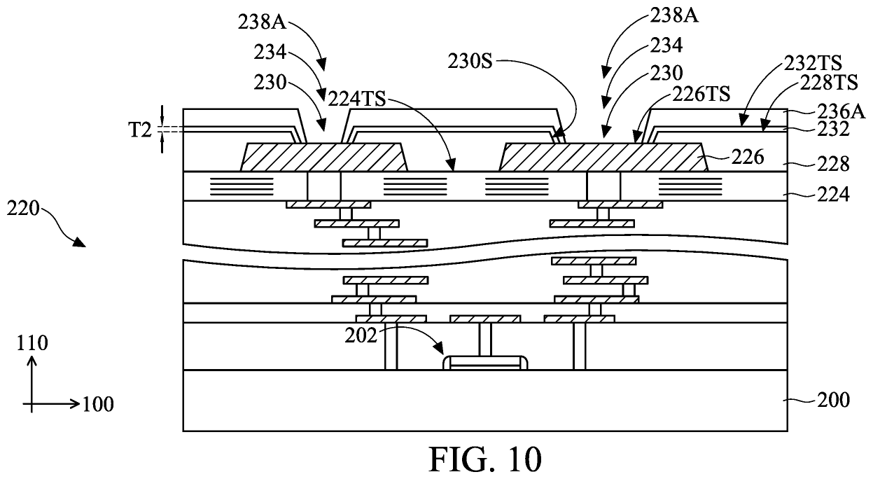

FIG. 10 is a schematic cross-sectional view of an intermediate stage of forming the semiconductor structure 500B of FIG. 2 in accordance with some embodiments of the disclosure. Elements of the embodiments hereinafter, that are the same or similar as those previously described with reference to FIGS. 1 to 9, are not repeated for brevity.

When the intermediate semiconductor structure 400 shown in FIG. 8 will be subjected the bumping process, processes similar to those shown in FIG. 9 are performed to form the opening 234 passing through the dielectric capping layer 232 to expose the portion of the conductive pad 226 in the opening 234 for the subsequent conductive bump structure 240 formed thereon. Next, as shown in FIG. 10, a coating process is performed to conformally forming the photosensitive stress buffer material layer 236A on the dielectric capping layer 232. The photosensitive stress buffer layer 236A may cover the top surface 232TS of the dielectric capping layer 232 and line the dielectric capping layer 232 in the opening 230 of the second passivation layer 228. Furthermore, the photosensitive stress buffer layer 236A may cover the top surface 226TS of the conductive pad 226 exposed from the opening 234 of the dielectric capping layer 232 (FIG. 9).

Next, a photolithography process including an exposure step and a development step is performed to form the opening 238A passing through the photosensitive stress buffer layer 236A to expose the portion of the conductive pad 226. The photosensitive stress buffer layer 236A is subjected to the photolithography process to remove a portion of the photosensitive stress buffer layer 236A directly on the portion of the conductive pad 226 in the opening 234 to form the opening 238A. The remaining photosensitive stress buffer layer 236A may cover the top surface 232TS of the dielectric capping layer 232 and line the dielectric capping layer 232 in the opening 230 of the second passivation layer 228. Next, the photosensitive stress buffer layer 236A having the opening 238A is subjected to a curing process to solidify the photosensitive stress buffer layer 236A. After the curing process, the level of the photosensitive stress buffer layer 236A may drop as a result of shrinkage of the photosensitive stress buffer layer.

Next, as shown in FIG. 2, the bumping process similar to those described referring to FIG. 1 is performed to form the conductive bump structure 240 on the second passivation layer 228, the dielectric capping layer 232 and the photosensitive stress buffer layer 236A. In addition, the conductive bump structure 240 is formed passing through the openings 230, 234 and 238A and connected to the conductive pad 226. After the aforementioned processes have been performed, the semiconductor structure 500B in accordance with some embodiments of the disclosure as shown in FIG. 2 is formed.

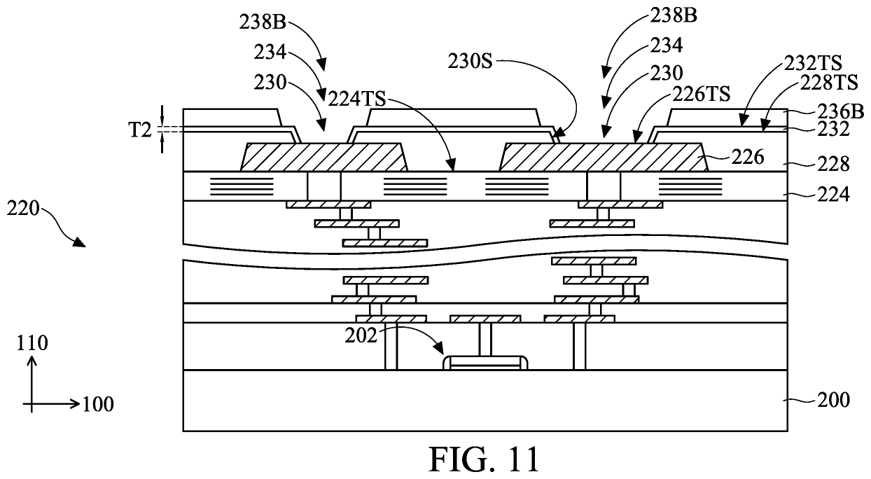

FIG. 11 is a schematic cross-sectional view of an intermediate stage of forming the semiconductor structure 500C of FIG. 3 in accordance with some embodiments of the disclosure. Elements of the embodiments hereinafter, that are the same or similar as those previously described with reference to FIGS. 1 to 10, are not repeated for brevity.

When the intermediate semiconductor structure 400 shown in FIG. 8 will be subjected the bumping process, processes similar to those shown in FIG. 9 are performed to form the opening 234 passing through the dielectric capping layer 232 to expose the portion of the conductive pad 226 in the opening 234 for the subsequent conductive bump structure 240 formed thereon. Next, as shown in FIG. 11, a coating process is performed to conformally forming the photosensitive stress buffer layer 236B on the dielectric capping layer 232. The photosensitive stress buffer layer 236B may cover the top surface 232TS of the dielectric capping layer 232 and line the dielectric capping layer 232 in the opening 230 of the second passivation layer 228. Furthermore, the photosensitive stress buffer layer 236B may cover the top surface 226TS of the conductive pad 226 exposed from the opening 234 of the dielectric capping layer 232 (FIG. 9).

Next, a patterning process (including a photolithography process including an exposure step and a development step) is performed to form the opening 238B passing through the photosensitive stress buffer layer 236B to expose the portion of the conductive pad 226 in the opening 234 and a portion of the dielectric capping layer 232 in the opening 230. A portion of the photosensitive stress buffer layer 236B lining the dielectric capping layer 232 in the opening 230 of the second passivation layer 228 and directly on the portion of the conductive pad 226 in the opening 234 to form the opening 238B are removed by the photolithography process.

Next, as shown in FIG. 3, the bumping process similar to those described referring to FIG. 1 is performed to form the conductive bump structure 240 on the second passivation layer 228, the dielectric capping layer 232 and the photosensitive stress buffer layer 236B. In addition, the conductive bump structure 240 is formed passing through the openings 230, 234 and 238B and connected to the conductive pad 226. After the aforementioned processes have been performed, the semiconductor structure 500C in accordance with some embodiments of the disclosure as shown in FIG. 3 is formed.

Embodiments provide a semiconductor structure. The semiconductor structure in accordance with some embodiments of the disclosure includes an interconnection structure, the topmost passivation layer, and a dielectric capping layer. The interconnect structure includes a conductive pad located at the top of the interconnection structure. The topmost passivation layer is disposed on the interconnection structure. The passivation layer has a first opening to expose a portion of the conductive pad. The dielectric capping layer is conformally formed on the topmost passivation layer and extending into the first opening. The dielectric capping layer has a second opening to expose the portion of the conductive pad. The dielectric capping layer may interpose between the second passivation layer and a subsequent conductive bump structure formed on the conductive pad. In some embodiments, the top surface of the conductive pad is fully covered by the topmost passivation layer and the dielectric capping layer before forming the second opening. In this stage, the dielectric capping layer may serve as a protection layer for the underlying the conductive pad. When the intermediate semiconductor structure including the conformally formed dielectric capping layer is in the long queue storage before performing the subsequent bumping process, the dielectric capping layer may prevent the conductive pad from oxidation. More specifically, the oxidation occurring at the interface between conductive pad and the overlying conductive bump structure can be avoid. When the intermediate semiconductor structure will be subjected the bumping process, the second opening is formed passing through the dielectric capping layer to expose the portion of the conductive pad in the first opening for the subsequent conductive bump structure formed thereon. Therefore, the parasitic RC of the conductive bump structure can be reduced, the reliability and manufacturing quality of the resulting semiconductor structure can be improved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
an interconnect structure comprising a conductive pad located at a top of the interconnection structure;
a passivation layer disposed on the interconnection structure, wherein the passivation layer has a first opening to expose a portion of the conductive pad; and
a dielectric capping layer conformally formed on the passivation layer and extending into the first opening, wherein the dielectric capping layer has a second opening to expose the portion of the conductive pad.

2. The semiconductor structure as claimed in claim 1, wherein a top surface of the dielectric capping layer is a flat surface.

3. The semiconductor structure as claimed in claim 1, wherein the first opening is aligned with the second opening, and the dielectric capping layer lines a first sidewall of the first opening and is in contact with the passivation layer and the portion of the conductive pad exposed from the first opening.

4. The semiconductor structure as claimed in claim 3, wherein in a direction substantially parallel to a top surface of the passivation layer, the first opening has a first dimension, and the second opening has a second dimension that is less than the first dimension.

5. The semiconductor structure as claimed in claim 1, wherein a thickness of the dielectric capping layer is between about 25 Å and 50 μm.

6. The semiconductor structure as claimed in claim 1, wherein a first angle between a first side surface of the dielectric capping layer in the first opening and away from the passivation layer and an top surface of the conductive pad is less than or equal to 95 degrees.

7. The semiconductor structure as claimed in claim 1, further comprising;
a photosensitive stress buffer layer conformally formed on the dielectric capping layer, wherein the photosensitive stress buffer layer has a third opening to expose the portion of the conductive pad.

8. The semiconductor structure as claimed in claim 7, wherein the second opening is aligned with the third opening.

9. The semiconductor structure as claimed in claim 7, wherein the photosensitive stress buffer layer lines a second sidewall of the second opening and is in contact with the dielectric capping layer and a portion of the conductive pad exposed from the second opening.

10. The semiconductor structure as claimed in claim 9, wherein in a direction substantially parallel to a top surface of the passivation layer, the second opening has a second dimension, and the third opening has a third dimension that is less than the second dimension.

11. The semiconductor structure as claimed in claim 9, wherein a second angle between a second side surface of the photosensitive stress buffer layer away from the dielectric capping layer located in the second opening and a top surface of the conductive pad is less than or equal to 95 degrees.

12. The semiconductor structure as claimed in claim 7, wherein the photosensitive stress buffer layer is spaced apart from the dielectric capping layer in the first opening.

13. The semiconductor structure as claimed in claim 12, wherein in a direction substantially parallel to a top surface of the passivation layer, the second opening has a second dimension, and the third opening has a third dimension that is greater than the second dimension.

14. The semiconductor structure as claimed in claim 12, wherein a third angle between a second side surface of the photosensitive stress buffer layer surrounding the third opening and a bottom surface of the photosensitive stress buffer layer is less than or equal to 95 degrees.

15. The semiconductor structure as claimed in claim 1, wherein the interconnect structure further comprises a first passivation layer disposed underlying the conductive pad, wherein the passivation layer is a second passivation layer covering the first passivation layer.

16. The semiconductor structure as claimed in claim 15, further comprising;
a conductive bump structure disposed on the second passivation layer, passing through the first opening and the second opening and connected to the conductive pad, wherein the dielectric capping layer is interposed between the second passivation layer and the conductive bump structure.

17. The semiconductor structure as claimed in claim 16, wherein the conductive bump structure and the conductive pad comprise the same material.

18. The semiconductor structure as claimed in claim 16, wherein the second passivation layer and the dielectric capping layer are formed of different materials.

19. A method for forming a semiconductor structure, comprising:
forming an interconnect structure on a substrate, wherein the interconnect structure comprises:
a conductive pad located at a top of the interconnection structure; and
a first passivation layer disposed underlying the conductive pad;
forming a second passivation layer on the interconnection structure;
forming a first opening passing through the second passivation layer to expose a portion of the conductive pad; and
conformally forming a dielectric capping layer on the second passivation layer, wherein a top surface of the conductive pad is fully covered by the first passivation layer and the dielectric capping layer before forming a conductive bump structure on the conductive pad.

20. The method for forming a semiconductor structure as claimed in claim 19, wherein forming the second passivation layer further comprises:
forming a lower portion of the second passivation layer covering a top surface of the conductive pad, wherein the top surface of the conductive pad is a convex surface;
performing a planarization process to remove a portion of the lower portion of the second passivation layer and a portion of the conductive pad, wherein the top surface of the conductive pad is a flat surface and level with a top surface of the lower portion of the second passivation layer after performing the planarization process; and
forming an upper portion of the second passivation layer covering the lower portion of the second passivation layer and the top surface of the conductive pad.

21. The method for forming a semiconductor structure as claimed in claim 19, further comprising:
forming a second opening passing through the dielectric capping layer to expose the portion of the conductive pad; and
forming the conductive bump structure on the second passivation layer, passing through the first opening and the second opening and connected to the conductive pad.

22. The method for forming a semiconductor structure as claimed in claim 19, further comprising:
conformally forming a photosensitive stress buffer layer on the dielectric capping layer; and
forming a third opening passing through the photosensitive stress buffer layer to expose the portion of the conductive pad.

23. The method for forming a semiconductor structure as claimed in claim 22, further comprising:
performing a photolithography process to remove a portion of the photosensitive stress buffer layer directly on the portion of the conductive pad in the second opening to form the third opening.

24. The method for forming a semiconductor structure as claimed in claim 22, further comprising:
performing a photolithography process to remove a portion of the photosensitive stress buffer layer lining the dielectric capping layer in the first opening and directly on the portion of the conductive pad in the second opening to form the third opening.
